(19) United States
(12) Patent Application Publication
(10) Pub. No.: US 2009/0224328 A1
(43) Pub. Date: Sep. 10, 2009

(54) SEMICONDUCTOR DEVICE

(76) Inventors: Shyh-Fann Ting, Tai-Nan City (TW); Cheng-Tung Huang, Kao-Hsiung City (TW); Kun-Hsien Lee, Tai-Nan City (TW); Wen-Han Hung, Kao-Hsiung City (TW); Meng-Yi Wu, Kaohsiung County (TW); Li-Shian Jeng, Tai-Tung Hsien (TW); Chung-Min Shih, Tai-Nan City (TW); Tzyy-Ming Cheng, Hsin-Chu City (TW); Jing-Chang Wu, Yun-Lin Hsien (TW); Tzer-Min Shen, Nantou City (TW)

Correspondence Address: NORTH AMERICA INTELLECTUAL PROPERTY CORPORATION, P.O. BOX 506, MERRIFIELD, VA, 22116, US

(21) Appl. No.: 12/041,668

(22) Filed: Mar. 4, 2008

(51) Int. Cl. H01L 29/78; H01L 21/336

(52) U.S. Cl. 257/368; 438/294; 257/E29.255; 257/E21.409

(57) ABSTRACT

A semiconductor device includes a substrate defining an active area thereon, a shallow trench isolation on the substrate and directly surrounding the active area, a gate, a source and a drain on the active area and a hard mask on the border of the shallow trench isolation and the active area.

### BACKGROUND OF THE INVENTION

1. Field of the Invention

The present invention relates to a semiconductor device. More particularly, the present invention relates to a semiconductor device with protected shallow trench isolations.

2. Description of the Prior Art

To increase the carrier mobility in the gate channel of a semiconductor, increasing or decreasing the strain in the gate channel to modify the strain in the gate channel is widely used in the current techniques to finally increase the carrier mobility in the gate channel. For example, in a PMOS, a pair of trenches are formed in the source/drain near the gate channel, then materials such as SiGe are filled in the trenches to replace part of the silicon substrate. Strained-Si is therefore formed by taking advantage of Ge being larger than Si to generate additional compression force in the gate channel to enhance the carrier mobility in the gate channel.

FIG. 1 illustrates that the SiGe material is used to increase the strain in the gate channel in the prior art. As shown in FIG. 1, there are P-type MOS 101 and N-type MOS 102 on the silicon substrate 110. First, a patterned cap layer 103 is formed on the silicon substrate 110 to cover the NMOS 102. Then, under the protection of the cap layer 103, the source/drain of PMOS 101 is etched and cleaned.

Afterwards, as shown in FIG. 2, the SiGe layer 111 is formed by epitaxy to replace part of the silicon substrate 110 in the source/drain of PMOS 101. At present, the edges of the shallow trench isolation 130 formed of oxide are damaged by the previous etching or cleaning process to cause damage 131. Later, the trenches cannot be completely filled because SiGe is opt to grow along with the intrinsic lattice of the silicon substrate 110 when SiGe is back-filled, therefore a gap 132 is formed between the active area 120 and the shallow trench isolation 130 of the PMOS 101. In addition, as shown in FIG. 3, the shallow trench isolation 130 is again damaged when the cap layer 103 is removed. As a result, the gap 132 plus the damage 131 altogether cancel much of the compression force created by the SiGe layer 111, and the following self-aligned silicide (salicide) may extend into the silicon substrate 110 along the direction of the gap 131 to form other disadvantageous effects.

Additionally, because the shallow trench isolation 130 adjacent to the active area 120 is not shielded by the cap layer 103, the top side of the shallow trench isolation 130 will suffer loss due to the previous etching or cleaning, so that each top side of the shallow trench isolations 130 is not on a level with each other relative to the substrate after the following removal of the cap layer 103 on the active area 120, i.e., the top side of the shallow trench isolation 130 adjacent to the active area 120 is lower than that of the shallow trench isolation 130 adjacent to the active area 121 so that the difficulty of the following steps is much higher.

Therefore, a novel semiconductor device and a manufacturing process thereof are needed to solve the problems, so that gaps between the active area and the shallow trench isolation will not form during the etching and cleaning of source/drain, and the removal of the cap layer in order to maintain the strain and the carrier mobility in the gate channel.

### SUMMARY OF THE INVENTION

The present invention hence provides a novel semiconductor device. The semiconductor device includes a mask to protect the fragile border between the active area and the shallow trench isolation. Accordingly, gaps between the active area and the shallow trench isolation will not form during the etching, cleaning of source/drain, and the removal of the cap layer. Such mask may completely solve the problems in the prior art. On one hand, the epitaxy layer may still correctly change the strain in the gate channel, and on the other hand, salicide may be formed as expected.

The present invention first provides a semiconductor device, including a substrate defining an active area thereon, a shallow trench isolation on the substrate and directly surrounding the active area, a gate on the active area, a source in the active area on one side of the gate, a drain in the active area on another side of the gate and a hard mask on the border of the shallow trench isolation and the active area.

The present invention further provides a method for forming a semiconductor. The method first provides a substrate defining an active area and a shallow isolation directly surrounding the active area. Then a gate is formed on the active area. Afterwards, a hard mask is formed on the border of the shallow trench isolation and the active area. Later a source and a drain is formed respectively on one side of the gate to complete the formation of the semiconductor of the present invention. The semiconductor may include two or more semiconductor devices. The hard mask may be an extension of an adjacent gate or electrically connected to the gate of its own.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-3 illustrate SiGe used to increase the strain in the gate channel in the prior art.

FIGS. 4-9 illustrate a preferred embodiment of forming the semiconductor device of the present invention.

FIGS. 10-11 illustrate a preferred embodiment of the shape of the hard masks of the semiconductor device of present invention.

FIG. 12 illustrates various variations of the hard masks of the semiconductor device of present invention.

FIG. 13 illustrates a section view of the semiconductor device of the present invention.

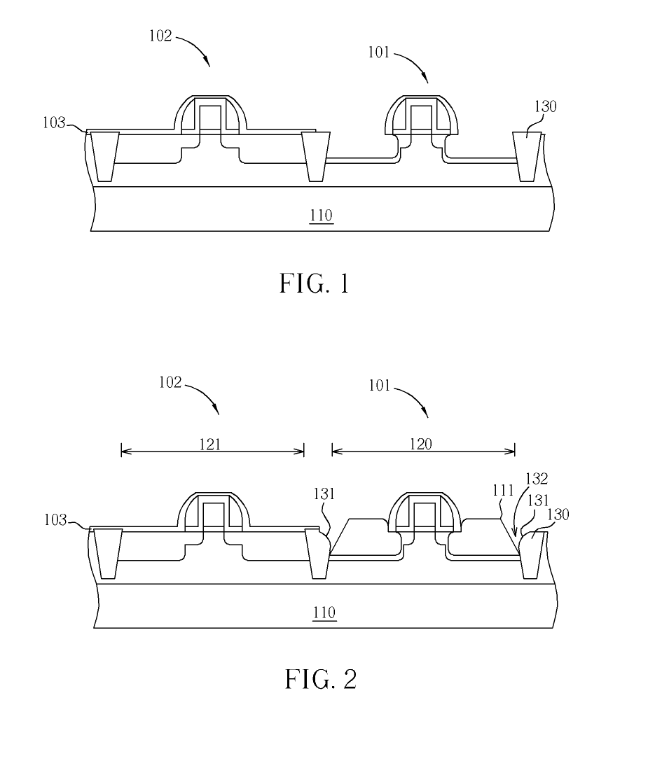

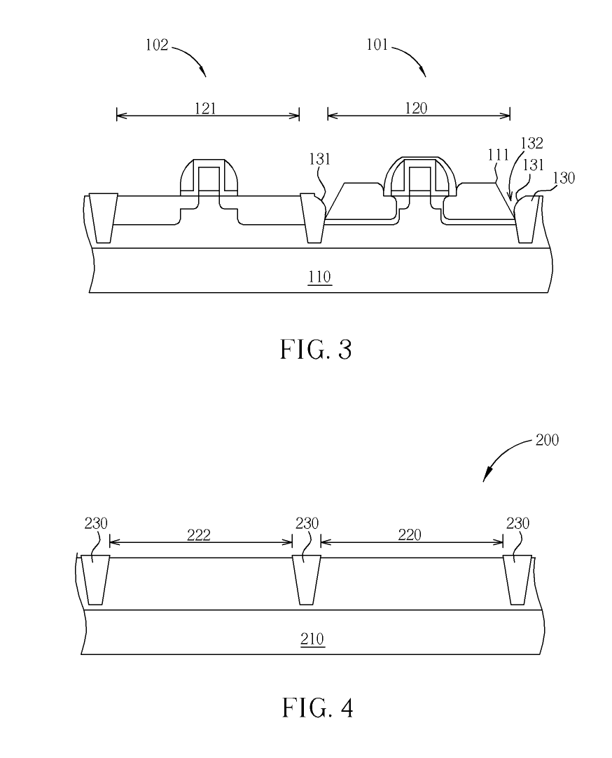

### DETAILED DESCRIPTION

The present invention is to provide a novel semiconductor device to solve the problem of the formation of gaps between the fragile border along the active area and the shallow trench isolation when the source/drain are etched, cleaned and the cap layer is removed. On one hand, the object to change the strain in the gate channel by using epitaxy layer is not compromised, and on the other hand, the salicide may be formed as expected.

Please refer to FIGS. 4-10, illustrating a preferred embodiment of forming the semiconductor device of the present invention. The method discloses the formation of two or more semiconductor devices, such as P-type metal-oxide semiconductor (PMOS) 201 and N-type metal-oxide semiconductor (NMOS) 202 simultaneously or in sequential order respectively on the active area 220/222 of the substrate 210; at least one of the metal-oxide semiconductors is a strained-MOS. The following example is illustrated by forming an NMOS 202 and a strained-Si PMOS 201, but not limited to this. However, the present invention may also include strained-Si N-type or P-type CMOS.

As shown in FIG. 4, the method for forming the semiconductor device 200 of the present invention first provides a substrate 210. There are active areas 220/222 and shallow trench isolations 230 directing surrounding the active areas 220/222 defined on the substrate 210. The substrate 210 may usually be a semiconductor material, such as single crystal Si or SOI. The shallow trench isolation 230 may usually include an insulating material, such as silicon oxide. The methods for forming the shallow trench isolations 230 are well known by persons of ordinary skill in the art and the details will not be discussed.

Afterwards, as shown in FIG. 5, the required gate 240 structures which include gate dielectric layers, gate conductive layers and spacers 242 are respectively formed on the PMOS 201 and the NMOS 202 of the active areas 220/222 by sequentially performing depositing and patterning steps. The spacers 242 may optionally be disposable spacers. In other words, if the spacers 242 are disposable spacers, the spacers 242 may be removed after the selective epitaxial growth (SEG) procedure is completed.

Please notice that in a preferred embodiment of the present invention dummy gates 271 as a hard mask for protection are formed on the border of the active area 220 about to form strained Si structure PMOS 201 and the shallow trench isolation 230. That is, the layout of the dummy gates 271 as hard masks are determined when the reticle for the gate conductor of the PMOS 201 and the NMOS 202 is manufactured. Besides, the location of the dummy gates 271 as hard masks may be determined according to the ultra mathematical calculation. Accordingly, the dummy gates 271 may also include gate dielectric layers, gate conductive layers and spacers 272 so as to be precisely disposed on the border of the active areas 220 and the shallow trench isolation 230.

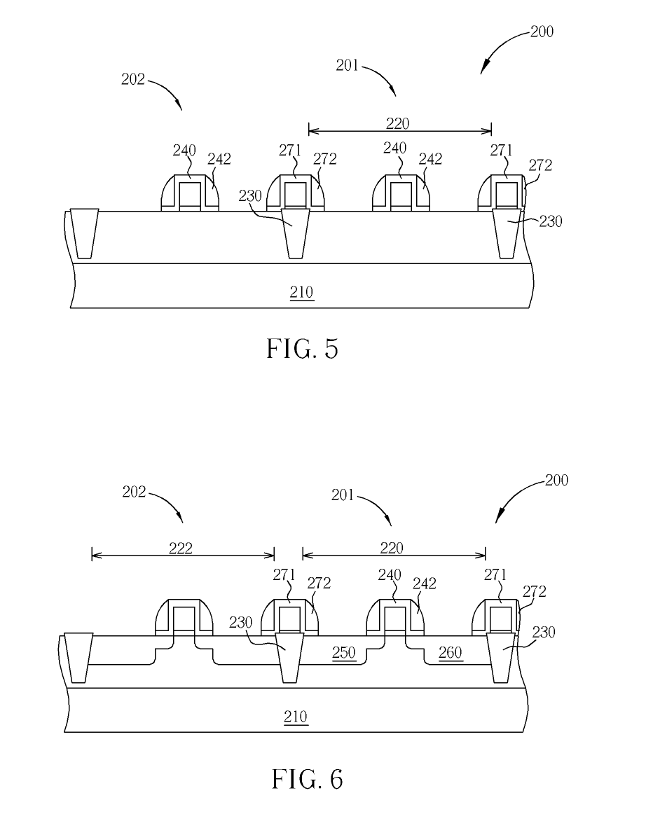

As shown in FIG. 6, a proper ion implanting step is performed to form the source 250/drain 260 of the PMOS 201 to be respectively on either side of the gate 240 of the PMOS 201. Please notice that the location of the source 250/drain 260 is arbitrary according to the required electric property. Besides, another ion implanting step may be performed to form the LDD of the PMOS 201 before the formation of the spacer 242.

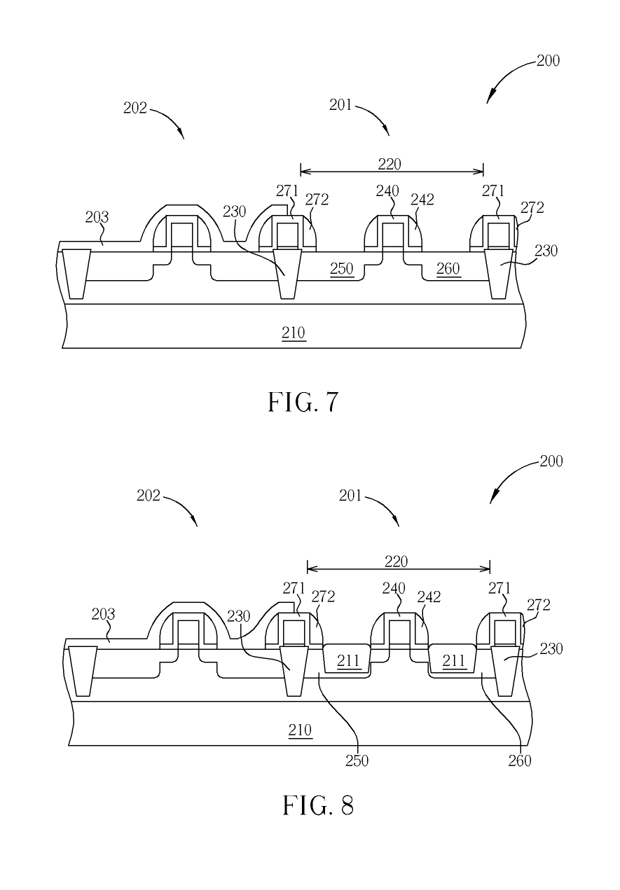

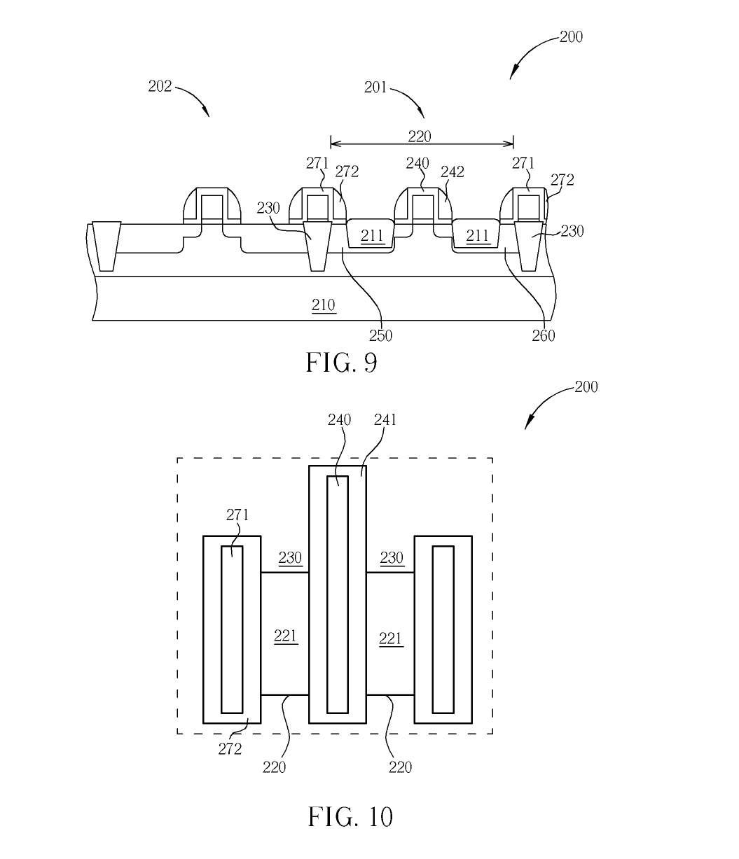

Afterwards, the strained layer is formed on the Si substrate 210. For example, first a patterned cap layer 203 may be formed on the Si substrate 210 to cover the NMOS 202, as shown in FIG. 7. Later, as shown in FIG. 8, steps such as etching or cleaning are performed on the source 250/drain 260 of the PMOS 201 under the protection of the cap layer 203. The required SiGe layer 211 to replace part of the Si substrate 210 in the source 250/drain 260 of the PMOS 201 are formed by selective epitaxial growth (SEG), to increase the compression stress in the gate channel of the PMOS 201 and to further enhance the carrier mobility in the gate channel.

In one preferred embodiment, the border of the shallow trench isolation 230 formed of oxide will not suffer damage due to the aforesaid etching or cleaning steps because the border of the shallow trench isolation 230 adjacent to the active areas 220 is protected by the dummy gates 271 as hard masks. In addition, as shown in FIG. 9, the shallow trench isolation 230 is still free from a second damage for the protection of the dummy gate 271 when the cap layer 203 is removed. Therefore, no gaps exist between the border of the shallow trench isolation 230 and the substrate, and the shallow trench isolation 230 is not damaged. So, the SiGe layer 211 may correctly apply a compression stress in the gate channel, and the salicide may be correctly formed as expected in the following salicide step. Moreover, because the top side of the shallow trench isolation 230 adjacent to the active areas 220 is protected by the dummy gates 271 free from being damaged by etching or cleaning, the top sides of each shallow trench isolations 230 on the substrate 210, i.e. the top side of the shallow trench isolation 230 adjacent to the active areas 220 protected by the dummy gates 271 as the hard mask, is of the same height of that of the shallow trench isolation 230 adjacent to the active areas 222 covered by the cap layer 203 relative to the surface of the substrate 210.

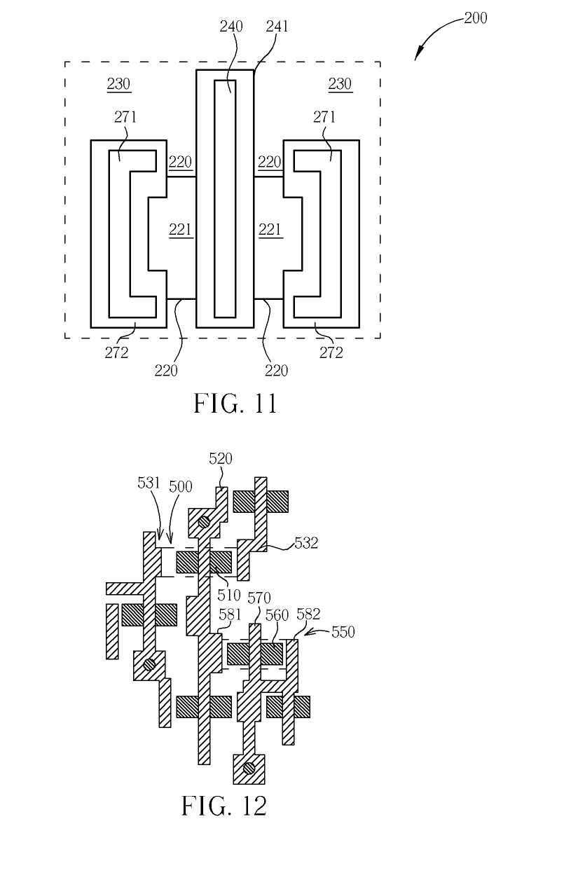

Please notice, in a preferred embodiment of the present invention, the shape and the layout of the dummy gate 271 as the hard mask may have various variations. As illustrated in FIG. 10, the dummy gates 271 as the hard mask is rectangular, such rectangle, extending along the border between the shallow trench isolation 230 and the active area 220. The trench region 221 for accommodating the strain material lies in the active area 220. For example, if the width between the gate 240 and the dummy gates 271 is 0.14 μm, the trench region 221 itself may have a width of 0.11 μm, so that the border of the trench region 221 is 0.03 μm from the dummy gates 271 as the hard mask and the trench region 221 is adjacent to the shallow trench isolation 230.

On the other side, please refer to the hard mask illustrated in FIG. 11, the dummy gates 271 as the hard mask is a polygon, such as ␣-shaped, not only extending along the border between the shallow trench isolation 230 and the active area 220 and simultaneously covers at least one corner of the shallow trench isolation 230 and the active area 220.

In addition, in order to go with the practical processes and various layout designs of the semiconductor, the hard mask of the present invention may have various variations. For example, please refer to FIG. 12, each PMOS 500 and NMOS 550 includes an active area 510/560 and a gate 520/570. Each of the hard masks 531/532/581/582 may be an extension of an adjacent gate or electrically connected to an adjacent gate. For example, the hard masks 531/532 of the PMOS 500 are extensions of adjacent and other different gates, so that the adjacent gates are transformed to widen the width to cover the border between the shallow trench isolation (not shown) and the active area 510 of the PMOS 500. If the hard masks are extensions of adjacent gates, the layout pattern of each gate should meet the design rules, such as the Optical Proximity Correction.

On the other hand, as shown in FIG. 12, the hard masks of the semiconductor devices may be the extensions of their own gates or electrically connected to their own gates. For example, the hard mask 581 of the NMOS 550 is an extension of an adjacent but different gate, and the hard mask 582 is the extension of its own gate. Now the adjacent/its own gate are transformed to widen the width to cover the border between the shallow trench isolation (not shown) and the active area 560 of the NMOS 550. The width of the hard masks should be different from at least one of the width of its own gate and the adjacent gate. Similarly, any two of adjacent shallow trench isolations, i.e. the top side of the shallow trench isolation protected by the hard mask of the present invention is of the same height of that of the shallow trench isolation which is not protected by the hard mask but covered by the cap layer relative to the surface of the substrate because the shallow trench isolations adjacent to each active area protected by the hard mask or the cap layer are free from the damage of etching or cleaning.

To sum up, in this preferred embodiment the dummy gates as hard masks for protection are simultaneously formed on the border of the active area and the shallow trench isolation of the MOS intended to form the strained-Si structure when the required conductor pattern is formed, so the border of the shallow trench isolation by the adjacent active area is free from the damage of etching and cleaning, and the top sides of each shallow trench isolations on the substrate are less likely damaged by etching or cleaning and of the same height relative to the surface of the substrate.

Moreover, the semiconductor device and the method are useful in any semiconductor device with gate channel strain, for example in PMOS with epitaxy compression strain by SiGe, in NMOS with epitaxy tension by SiC, or P-type/N-type CMOS with strain-Si structure. The hard mask may not be the extension of the gate and the methods/materials for manufacturing may be different.

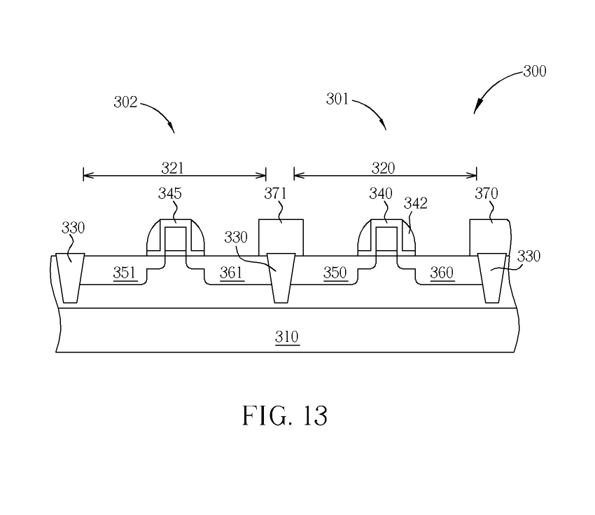

Please refer to FIG. 13, illustrating a cross-section view of another preferred embodiment of the semiconductor device of the present invention. The semiconductor device 300 of the present invention includes a substrate 310, on which a first active area 320/second active area 321 are defined, for respectively accommodating the elements of the semiconductor device 300 of the present invention, PMOS 301 and NMOS 302 for example. The first shallow trench isolation 330 is on the substrate 310 and directly surrounding the first active area 320. Similarly, the second shallow trench isolation 331 is on the substrate 310 and directly surrounding the second active area 321. The substrate 310 is usually a semiconductor material, such as single crystal Si or SOI. The shallow trench isolations 330/331 usually include an insulation material, such as silicon oxide.

The first active area 320 on which the PMOS 301 of the present invention is disposed includes a gate 340, a source 350 and a drain 360. The gate 340 is on the first active area 320 and further includes a gate dielectric layer (not shown), gate conductive layer (not shown) and a first spacer 342. On one hand, the source 350 is in the first active area 320 and adjacent to one side of the gate 340. On the other hand, the drain 360 is in the first active area 320 and adjacent to another side of the gate 340. Please notice that the location of the source 350/drain 360 is arbitrary. The NMOS 302 in the second active area 321 includes the gate 345, the source 351 and the drain 361. The first spacer 342 may optionally be a disposable spacer. In other words, if the first spacer 342 is a disposable spacer, the first spacer 342 may be removed after the selective epitaxial growth (SEG) procedure is completed.

Please notice because the PMOS 301 in this preferred embodiment is a MOS intended to form the strained-Si structure, there are hard masks 370/371 disposed on the border of the first shallow trench isolation 330 and the substrate 310 in the first active area 320, for covering the border of the first shallow trench isolation 330 and the first active area 320. The hard masks 370/371 may include materials, for example silicon oxide, silicon nitride and photoresist, resistant to the steps which perform etching and cleaning on the Si substrate and on the cap layer. Furthermore, in the preferred embodiment the location of the hard masks 370/371 may be determined according to the ultra mathematical calculation. Besides, in the preferred embodiment the hard masks 370/371 may be formed before/simultaneously/after the formation of a cap layer, and the shape as well as the layout of the hard masks 370/371 may have various variations, as shown in FIGS. 10-12. Other steps such as epitaxy step and salicide steps are similar to what is illustrated before and the details will not be discussed here.

Because hard masks of the present invention are formed on the border of the shallow trench isolation and the active area of the MOS with intended strained-Si structure, the border of shallow trench isolations adjacent to active areas are protected to be free from the damage of etching or cleaning, and the top sides of shallow trench isolations on the substrate are less likely damaged by etching or cleaning, so that the top sides of shallow trench isolations are of the same height relative to the substrate.

Those skilled in the art will readily observe that numerous modifications and alterations of the device and method may be made while retaining the teachings of the invention.

What is claimed is:

1. A semiconductor device, comprising:
a substrate defining a first active area thereon;
a first shallow trench isolation disposed on said substrate and directly surrounding said first active area;
a first gate disposed on said first active area;
a first source disposed in said first active area at one side of said first gate;
a first drain disposed in said first active area at another side of said first gate; and
a hard mask disposed on a border between said first shallow trench isolation and said first active area.

2. The semiconductor device of claim 1, wherein said hard mask is rectangular and extending along said border between said first shallow trench isolation and said first active area.

3. The semiconductor device of claim 1, wherein said hard mask is ␣-shaped and covers at least one corner of said first shallow trench isolation and said first active area.

4. The semiconductor device of claim 1, further comprising a second active area, a second shallow trench isolation surrounding said second active area, and a second metal-oxide semiconductor disposed in said second active area and comprising a second gate, wherein said first shallow trench isolation, said first gate, said first source and said first drain together form a PMOS and said second metal-oxide semiconductor is an NMOS.

5. The semiconductor device of claim 1, wherein said hard mask is electrically connected to said first gate.

6. The semiconductor device of claim 4, wherein said hard mask is electrically connected to said second gate.

7. The semiconductor device of claim 4, wherein said first shallow trench isolation and said second shallow trench isolation are of the same height relative to said substrate.

8. The semiconductor device of claim 1, wherein the location of said hard mask is determined according to an ultra mathematical calculation.

9. The semiconductor device of claim 1, wherein said hard mask comprises a dummy gate and a dummy spacer.

10. The semiconductor device of claim 4, wherein the width of said hard mask is different from at least one of that of said first gate and said second gate.

11. A method for forming a semiconductor, comprising:
providing a substrate defining a first active area and a first shallow trench isolation directly surrounding said first active area;
forming a first gate disposed on said first active area;
forming a hard mask disposed on a border between said first shallow trench isolation and said first active area; and
forming a first source and a first drain respectively disposed on one side of said first gate.

12. The method of claim 11, wherein said hard mask is rectangular and extending along said border between said first shallow trench isolation and said first active area.

13. The method of claim 11, wherein said hard mask is ␣-shaped and covers at least one corner of said first shallow trench isolation and said first active area.

14. The method of claim 11, further comprising:
forming a second active area, a second shallow trench isolation surrounding said second active area and a second metal-oxide semiconductor disposed in said second active area and comprising a second gate, so that said first shallow trench isolation, said first gate, said first source and said first drain together form a PMOS and said second metal-oxide semiconductor forms an NMOS.

15. The method of claim 11, wherein said hard mask is electrically connected to said first gate.

16. The method of claim 14, wherein said hard mask is electrically connected to said second gate.

17. The method device of claim 14, wherein said first shallow trench isolation and said second shallow trench isolation are of the same height relative to said substrate.

18. The method of claim 11, further comprising:
using an ultra mathematical calculation to determine the location of said hard mask.

19. The method of claim 11, wherein said hard mask comprises a dummy gate and a dummy spacer.

20. The method of claim 11, wherein the width of said hard mask is different from at least one of that of said first gate and said second gate.
